(19) United States
(12) Patent Application Publication
(10) Pub. No.: US 2013/0063899 A1
(43) Pub. Date: Mar. 14, 2013

(54) HEAT DISSIPATING STRUCTURE OF ELECTRONIC APPARATUS

(71) Applicant: Tatsuro Kuroda, Osaka (JP)

(72) Inventor: Tatsuro Kuroda, Osaka (JP)

(73) Assignee: SHARP KABUSHIKI KAISHA, Osaka (JP)

(21) Appl. No.: 13/698,710

(22) PCT Filed: Jan. 24, 2011
(86) PCT No.: PCT/JP2011/051202

§ 371 Date: Nov. 19, 2012

(30) Foreign Application Priority Data
May 24, 2010 (JP) 2010-118535

(51) Int. Cl. H05K 7/20

(52) U.S. Cl. 361/718

(57) ABSTRACT

Disclosed is a heat dissipation structure of an electronic device that has an IC chip that is a heat generating element mounted on a substrate and a heat dissipation sheet disposed between the IC chip and a cover member so as to dissipate heat. In such a heat dissipation structure, even if variation in a gap between the IC chip and the cover member is generated, the heat dissipation sheet can come in contact with the IC chip and with the cover member with appropriate pressure. This way, heat is sufficiently dissipated, and therefore, reliability of the electronic device can be improved. A heat dissipation sheet (1) has a double-layered structure in which a first heat dissipation sheet (11) and a second heat dissipation sheet (12) are laminated in a thickness direction. A rubber hardness of the first heat dissipation sheet is set different from that of the second heat dissipating sheet, and a softer heat dissipation sheet and a harder heat dissipation sheet are laminated in a direction of the gap between an IC chip (3) and a cover member (4).

### TECHNICAL FIELD

The present invention relates to a heat dissipation structure of an electronic device used for a liquid crystal display device and the like.

### BACKGROUND ART

In recent years, electronic devices that are provided with substrates having electronic components such as IC chips (semiconductor chips) mounted thereon have been widely available. On substrates for driving liquid crystal display panels of liquid crystal display devices, for example, large numbers of such electronic components are mounted.

The density of the electronic components that are used in various electronic devices has been increased in order to respond to sizes of the electronic devices being reduced. Arranging the electronic components such as IC chips densely in a small space results in a serious heat problem that requires a measure to dissipate heat.

The electronic components such as IC chips mounted on the substrate undergo change in characteristics due to increase in temperature caused by heat generation upon using the electronic device. This may cause device malfunction and electronic component failure. Therefore, a heat dissipation structure for suppressing an increase in temperature of the electronic components such as IC chips has been conventionally proposed.

A heat dissipation structure of using a heat dissipation plate for dissipating heat generated in the electronic components such as IC chips has been proposed, for example. Also, a heat dissipation structure of having a rubber sheet with heat conductivity disposed between a heat dissipation plate and IC chips and immediately transmitting heat from the IC chips to the heat dissipation plate through the rubber sheet has been proposed.

In case of having a plurality of IC chips mounted on the same substrate, a plurality of heat-generating elements are disposed close to each other. For electronic devices having such a configuration, it is required to dissipate heat from each of the IC chips even more rapidly.

However, when the heights of the respective mounted chips vary, which is caused by varied thicknesses thereof, a heat dissipation structure suited to each of the IC chips needs to be employed by placing rubber sheets or heat dissipation plates corresponding to the respective IC chips that have various heights.

For this purpose, heat dissipation sheets are directly disposed on the respective IC chips to dissipate heat from the respective IC chips. For example, a heat dissipation structure of an electronic device described as follows has been already proposed. In this heat dissipation structure of the electronic device, a silicon rubber sheet for heat dissipation is disposed between heat-generating elements mounted on a substrate and a metal case; heat from the heat-generating elements is transmitted immediately to the metal case; and the heat is dissipated outside of the device (see Patent Document 1, for example).

In a liquid crystal display device having a backlight that uses an LED (light-emitting diode) as a light source, LED chips themselves become heat-generating elements. Therefore, it is preferable that heat generated from the LED chips be immediately dissipated. To this end, a liquid crystal display device described as follows has been already proposed. In this liquid crystal display device, a metal case having an excellent heat dissipation characteristic is positioned using a fitting member and is attached such that heat generated from the LED chips is efficiently dissipated (see Patent Document 2, for example).

### RELATED ART DOCUMENTS

### Patent Documents

Patent Document 1: Japanese Patent Application Laid-Open Publication No. H10-308484

Patent Document 2: Japanese Patent Application Laid-Open Publication No. 2010-2745

### SUMMARY OF THE INVENTION

### Problems to be Solved by the Invention

Heat generated in heat-generating elements such as IC chips can be dissipated from a cover member by disposing a heat dissipation sheet having excellent heat conductivity such as a silicon rubber sheet between the heat-generating elements such as IC chips mounted on a substrate and the cover member that covers the substrate and that serves as a heat dissipation plate. Also, if the heat dissipation sheet to be used is soft, this heat dissipation sheet can address size variation of gaps between the respective heat-generating elements such as the IC chips and the cover member to some extent.

However, when mounting a plurality of IC chips having various heights on the same substrate, sizes of respective gaps between the respective IC chips and a substrate cover vary. Consequently, contact pressures between the respective IC chips and the heat dissipation sheet vary, which results in a problem of decreased heat dissipation performance. Therefore, it is preferable that the heat dissipation sheet having an appropriate thickness suited for the gap sizes be disposed.

By providing chip pressing members that have heat conductivity and that are made of protrusions formed on a substrate cover, heat dissipation sheets that have a uniform thickness may be disposed. In this case, it is necessary to form the chip pressing members in advance to have prescribed protrusion heights corresponding to the respective thicknesses of the chips that are mounted. However, if a dimension error is made upon fabrication, the protrusion height becomes different from the prescribed height. This leads to a problem of having too small or too large contact pressure.

When a sheet-like soft heat dissipation sheet is pressed and attached on the IC chip by the chip pressing member, the contact pressure is higher in a periphery of the IC chip, but is lower in the center of the IC chip. This results in a problem of degradation of the heat dissipation performance.

If the contact pressure between the heat dissipation sheets and the IC chips is small, or if the heat dissipation sheets fall off from the IC chips due to the contact pressure being too small, heat dissipation performance is degraded, resulting in a problem. On the other hand, if the contact pressure is too high, the substrate is bent and damaged or the IC chips are damaged, resulting in a problem.

In order to avoid such problems, it is preferable that the heat dissipation structure be configured such that, even if the heights of the plurality of the respective IC chips mounted on the substrate vary, the heat dissipation sheets do not fall off upon being attached to the IC chips, and reliably come in contact with the entire surfaces of the respective IC chips with an appropriate contact pressure, thereby reliably dissipating heat.

The present invention was made in view of the above problems, and aims at providing a heat dissipation structure of an electronic device that includes IC chips, i.e., heat generating elements, mounted on a substrate, and heat dissipation sheets respectively interposed between the IC chips and a cover member so as to dissipate heat and that allows, even if variation in gaps between the respective IC chips and the cover member is generated, the heat dissipation sheets to make contact with the IC chips and with the cover member, respectively, with an appropriate pressure so as to dissipate heat sufficiently and to improve reliability of the electronic device.

### Means for Solving the Problems

In order to achieve the above object, the present invention is a heat dissipation structure of an electronic device that is provided with: a substrate having an IC chip, which is an electronic component that becomes a heat-generating element, mounted thereon; a cover member that covers a mounting surface of the substrate and that has a heat dissipation characteristic; and a heat dissipation sheet interposed and pressed between the IC chip and the cover member, the heat dissipation structure dissipating heat through the heat dissipation sheet and the cover member, wherein the heat dissipation sheet has a double-layered structure in which a first dissipation sheet and a second heat dissipation sheet are laminated in a thickness direction, and wherein a rubber hardness of the first heat dissipation sheet differs from that of the second heat dissipation sheet so that a softer heat dissipation sheet and a harder heat dissipation sheet are laminated in a direction of a gap between the IC chip and the cover member.

According to this configuration, it becomes possible to address the variation in the gap between the IC chip and the cover member with ease by the softer heat dissipation sheet having a lower rubber hardness. Further, the harder heat dissipation sheet overlaid on the softer heat dissipation sheet prevents the softer heat dissipation sheet from being excessively deformed. Therefore, the heat dissipation sheet can come in contact with the IC chip with uniform contact pressure. As a result, the present invention can achieve a heat dissipation structure of an electronic device that allows, even if variation in the gap between the IC chip and the cover member is generated, the heat dissipation sheet to come in contact with the IC chip and with the cover member with appropriate pressure. This way, the heat is reliably dissipated, and therefore, reliability of the electronic device can be improved.

In the above heat dissipation structure of the electronic device of the present invention, the first heat dissipation sheet has a chip contact surface with which the IC chip comes in contact and a bonding surface on which the second heat dissipation sheet is bonded, the second heat dissipation sheet has a bonding surface on which the first heat dissipation sheet is bonded and a cover contact surface with which the cover contact member comes in contact, and the respective contact surfaces are substantially flat. One heat dissipation sheet, which is harder, is made thick in a center and is made thin in a periphery in a thickness direction such that the bonding surface thereof forms a mountain shape in a cross-sectional view, and the other heat dissipation sheet, which is softer, is made thin in a center and is made thick in a periphery in a thickness direction such that the bonding surface thereof forms a reverse mountain shape in a cross-sectional view. According to this configuration, the center of the harder heat dissipation sheet is formed thick and the center of the softer heat dissipation sheet is formed thin. Therefore, contact pressure is increased in the center of the IC chip that comes in contact with the heat dissipation sheet and becomes unlikely to be decreased, which makes it easy to have the heat dissipation sheet reliably come in contact with an entire surface of the IC chip. As a result, the heat dissipation sheet can come in contact with the IC chip with appropriate pressure, and the desired heat dissipation effect can be achieved.

In the above heat dissipation structure of the electronic device of the present invention, the first heat dissipation sheet has a chip contact surface with which the IC chip comes in contact and a bonding surface on which the second heat dissipation sheet is bonded, the second heat dissipation sheet has a bonding surface on which the first heat dissipation sheet is bonded and a cover contact surface with which the cover member comes in contact, and the respective contact surfaces are substantially flat. Further, a recess in a size that substantially coincides with that of the IC chip having the heat dissipation sheet placed thereon is made in a center of the contact surface of one heat dissipation sheet, which is harder, so that a hollow in a size corresponding to that of the IC chip is made in a center of a contact portion where the first heat dissipation sheet comes in contact with the second heat dissipation sheet. According to this configuration, the softer heat dissipation sheet is disposed on the IC chip with appropriate pressure through the hollow in a size that substantially coincides with that of the IC chip having the heat dissipation sheet placed thereon. Also, a region outside of the hollow in the softer heat dissipation sheet comes in contact with the harder heat dissipation sheet. Therefore, the softer heat dissipation sheet is prevented from being deformed, and the heat dissipation sheet can make uniform contact with the IC chip.

In the above heat dissipation structure of the electronic device of the present invention, the first heat dissipation sheet has a chip contact surface with which the IC chip comes in contact and a bonding surface on which the second heat dissipation sheet is bonded, the second heat dissipation sheet has a bonding surface on which the first heat dissipation sheet is bonded and a cover contact surface with which the cover member comes in contact, and the respective contact surfaces are substantially flat. Further, a recess in a size that substantially coincides with that of the IC chip having the heat dissipation sheet placed thereon is made in a center of the contact surface of the other heat dissipation sheet, which is softer. According to this configuration, the softer heat dissipation sheet can be attached so as to cover the IC chip through the recess in the size that substantially coincides with that of the IC chip having the heat dissipation sheet placed thereon. Also, a region outside of the recess in the softer heat dissipation sheet comes in contact with the harder heat dissipation sheet. Therefore, the softer heat dissipation sheet is prevented from being excessively deformed, and the heat dissipation sheet can make uniform contact with the IC chip with appropriate pressure.

In the above heat dissipation structure of the electronic device of the present invention, a chip pressing member is provided on the cover member and the chip pressing member presses each of the first and second heat dissipation sheets on the IC chip. According to this configuration, the heat dissipation sheet can come in contact with the IC chip with appropriate pressure by the chip pressing member. Also, the heat dissipation sheet can reliably come in contact with the cover member.

In the above heat dissipation structure of the electronic device of the present invention, the chip pressing member is an elastic pressing member provided with an elastic piece portion that is fixed to the cover member on one end and that is elastically moveable in a direction toward or away from the cover member, and a contact piece portion that is connected to the other end of the elastic piece portion and that comes in contact with the IC chip. According to this configuration, even if variation in a gap between the IC chip and the cover member is generated, the heat dissipation sheet comes in contact with the IC chip and with the cover member with appropriate pressure, thereby dissipating heat sufficiently. Therefore, the heat dissipation structure of the electronic device that can improve reliability of the electronic device is achieved.

In the above heat dissipation structure of the electronic device of the present invention, a base member having a substrate support leg that supports the substrate is provided on a rear surface of the substrate, a substrate support member that supports the substrate by sandwiching the substrate with the substrate support leg is provided on the cover member, and a middle portion support leg that supports a middle portion between a plurality of substrate pressing members is provided on the base member. According to this configuration, the substrate is sandwiched and supported, and also, even if the plurality of IC chips are mounted on the substrate, respective middle portions between the respective IC chips are supported. Therefore, the substrate is prevented from being bent or deformed, and even if the plurality of IC chips mounted on the substrate have mutually different heights, the heat dissipation sheets placed on the IC chips are reliably pressed on the IC chips. As a result, the heat dissipation sheet comes in contact with the IC chip and with the cover member with appropriate pressure, and heat is therefore dissipated sufficiently.

In the above heat dissipation structure of the electronic device of the present invention, the first heat dissipation sheet has a different hue from that of the second heat dissipation sheet. According to this configuration, the first heat dissipation sheet and the second heat dissipation sheet can be reliably laminated without confusing the two.

In the above heat dissipation structure of the electronic device of the present invention, a top surface of the second heat dissipation sheet, which corresponds to the cover contact surface, has a periphery thereof cut in a tapered shape. According to this configuration, the top surface of the heat dissipation sheet bonded on the IC chip has tapered corners. Therefore, it becomes difficult for the heat dissipation sheet to fall off upon being attached to the IC chip. As a result, the heat dissipation sheet can be reliably attached to the IC chip.

In the above heat dissipation structure of the electronic device of the present invention, a top surface of the second heat dissipation sheet, which corresponds to the cover contact surface, has a periphery thereof rounded in a circular arc shape. According to this configuration, the top surface of the heat dissipation sheet bonded on the IC chip has corners that are rounded in a circular arc shape. Therefore, it becomes difficult for the heat dissipation sheet to fall off upon being attached to the IC chip. As a result, the heat dissipation sheet can be reliably attached to the IC chip.

In the above heat dissipation structure of the electronic device of the present invention, the first heat dissipation sheet has a plurality of grooves on the bonding surface, and the plate-like second heat dissipation sheet is overlaid thereon. According to this configuration, when the heat dissipation sheet has a large surface area, by providing the plurality of grooves on the first heat dissipation sheet, variation in heights in a thickness direction can be suppressed and contact pressure can be averaged. Therefore, it becomes possible to prevent the contact pressure from being excessively decreased in the center of the IC chip coming in contact with the heat dissipation sheet.

In the above heat dissipation structure of the electronic device of the present invention, the grooves are rectangular. According to this configuration, by providing the rectangular grooves, which are easy to make, the contact pressure between the heat dissipation sheet and the IC chip and between the heat dissipation sheet and the cover member can be averaged.

In the above heat dissipation structure of the electronic device of the present invention, the first heat dissipation sheet is formed of a plurality of strip-like narrow sheets that are arranged to have a prescribed distance between each other, and the second heat dissipation sheet, which has a width wider than the width of the first heat dissipation sheet, is overlaid on the first heat dissipation sheet. According to this configuration, variation in heights in a thickness direction can be suppressed, and the contact pressure can be averaged. Further, the second heat dissipation sheet, which is wider than that of the first heat dissipation sheet, is overlaid on the first heat dissipation sheet. Therefore, an adverse effect caused by bumps such as burrs, splits, or the like, which tend to be formed at edges of the sheet as result of cutting, can be suppressed.

In the above heat dissipation structure of the electronic device of the present invention, the first heat dissipation sheet has the chip contact surface having a plurality of mountain-shaped projections that make the chip contact surface have a wave shape, and the second heat dissipation sheet, which has a wave-shaped contact surface that engages the wave shape of the first heat dissipation sheet, is overlaid on the first heat dissipation sheet. According to this configuration, variation in heights in a thickness direction can be suppressed, and the contact pressure can be averaged even if heat dissipation sheets respectively having large surface areas are laminated.

### Effects of the Invention

According to the present invention, in the heat dissipation structure of dissipating heat through the heat dissipation sheet disposed between the IC chip, which is a heat-generating element, mounted on the substrate, and the cover member, the softer heat dissipation sheet and the harder heat dissipation sheet are laminated in a direction of a gap between the IC chip and the cover member. Therefore, even if variation in gaps between the respective IC chips and the cover member is generated, it is possible to allow the heat dissipation sheet to come in contact with each IC chip and with the cover member with appropriate pressure. As a result, a heat dissipation structure of an electronic device that can dissipate heat sufficiently and that can improve reliability of the electronic device can be achieved.

### BRIEF DESCRIPTION OF THE DRAWINGS

FIG. 1A is a schematic side view showing a heat dissipation structure of an electronic device according to the present invention.

FIG. 1B is a schematic plan view showing the heat dissipation structure of the electronic device according to the present invention.

FIG. 2A is a cross-sectional view showing a heat dissipation sheet of Embodiment 1 according to the present invention.

FIG. 2B is a cross-sectional view showing a heat dissipation sheet of Embodiment 2 according to the present invention.

FIG. 2C is a cross-sectional view showing a heat dissipation sheet of Embodiment 3 according to the present invention.

FIG. 2D is a cross-sectional view showing a heat dissipation sheet of Embodiment 4 according to the present invention.

FIG. 3A is a plan view showing a first example of a heat dissipation sheet in a rectangular shape according to the present invention.

FIG. 3B is a plan view showing a second example of a heat dissipation sheet in a rectangular shape according to the present invention.

FIG. 3C is a plan view showing an example of a heat dissipation sheet in a circular shape according to the present invention.

FIG. 4A is an explanatory figure showing an example of attaching the heat dissipation sheet of Embodiment 3.

FIG. 4B is an explanatory figure showing an example of attaching the heat dissipation sheet of Embodiment 4.

FIG. 5A is an enlarged view showing a principal portion of an elastic pressing member, which is a modification example of a substrate pressing member.

FIG. 5B is an enlarged view showing a principal portion of the elastic pressing member that is attached.

FIG. 6 is a schematic cross-sectional view showing substrate support members sandwiching the substrate in a first modification example.

FIG. 7 is a schematic cross-sectional view showing substrate support members sandwiching the substrate in a second modification example.

FIG. 8A is an explanatory diagram showing an example of a heat dissipation sheet that has tapered-shaped corners.

FIG. 8B is an explanatory diagram showing an example of a heat dissipation sheet that has circular arc-shaped corners.

FIG. 8C is an explanatory diagram showing an example of a heat dissipation sheet that has a plurality of rectangular-shaped grooves.

FIG. 8D is an explanatory diagram showing an example of strip-like first heat dissipation sheets.

FIG. 8E is an explanatory diagram showing an example in which a first heat dissipation sheet and a second heat dissipation sheet that have mutually different widths are laminated.

FIG. 8F is an explanatory diagram showing an example of a heat dissipation sheet having a sandwich configuration.

FIG. 8G is an explanatory diagram showing an example of a heat dissipation sheet having a wave-shaped bonding surface.

### DETAILED DESCRIPTION OF EMBODIMENTS

Embodiments of the present invention will be described below with reference to figures. The same components are given the same reference characters, and a detailed description thereof is omitted where appropriate.

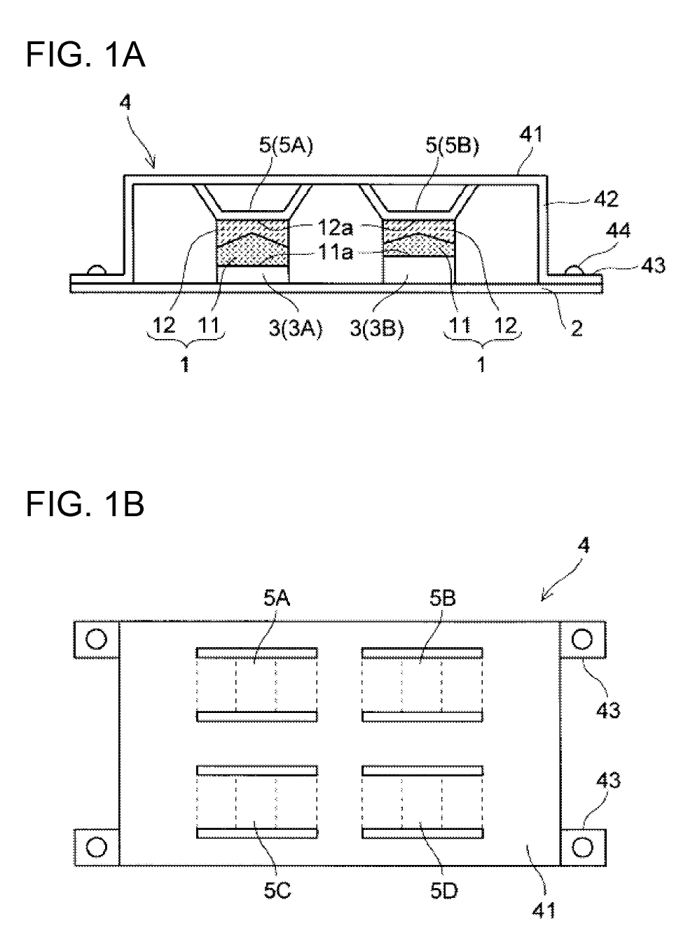

A heat dissipation structure of an electronic device according to this embodiment is a heat dissipation structure that relates to an electronic device provided with a substrate having electronic components such as IC chips (semiconductor chips) mounted thereon. As shown in FIG. 1A, for example, the heat dissipation structure dissipates heat through heat dissipation sheets 1 that are disposed between IC chips 3 (3A and 3B) mounted on a substrate 2 and a cover member 4 such as a substrate cover.

In the present embodiment, as shown in FIG. 1A, the heat dissipation sheet 1 has a double-layered structure of a first heat dissipation sheet 11 and a second heat dissipation sheet 12 being laminated in a thickness direction. Further, in this heat dissipation structure of the electronic device, a rubber hardness of the first heat dissipation sheet is set different from that of the second heat dissipation sheet so that a softer heat dissipation sheet and a harder heat dissipation sheet are laminated in a direction of a gap between the IC chips 3 and the cover member 4.

It is preferable that the softer heat dissipation sheet be a rubber sheet that is soft enough to be easily deformed in a thickness direction and that has a rubber hardness that allows the rubber sheet to be easily pressed against and reliably come in contact with the IC chips 3, regardless of size variation in respective gaps between the respective IC chips 3 and the cover member 4. A rubber sheet that has a heat dissipation characteristic such as a silicon rubber sheet or an acrylic rubber sheet and that has an Asker C hardness of about 10 to 30, for example, can be used for the softer heat dissipation sheet. It is preferable that the harder heat dissipation sheet be a rubber sheet harder than the softer heat dissipation sheet and have a sufficient rubber hardness to prevent the softer heat dissipation sheet bonded thereon from being excessively deformed. A rubber sheet that has a heat dissipation characteristic and that has an Asker C hardness of about 30 to 60, for example, is used for the harder heat dissipation sheet. The Asker C hardness is a standard measurement of a rubber hardness defined by the Society of Rubber Science and Technology, Japan, and corresponds to the Shore hardness E defined by JIS K 6253.

The respective heat dissipation sheets have bonding surfaces through which the respective heat dissipation sheets are bonded to each other and contact surfaces that respectively come in contact with the IC chip and with the cover member. If the first heat dissipation sheet 11, which is the harder heat dissipation sheet, is placed on the IC chip, and if the second heat dissipation sheet 12, which is the softer heat dissipation sheet, comes in contact with the cover member, for example, a contact surface 11a of the first heat dissipation sheet 11 becomes a chip contact surface, and a contact surface 12a of the second heat dissipation sheet 12 becomes a cover contact surface.

The cover member 4 is a substrate cover having a top surface 41, a side surface 42, and a mounting surface 43. The cover member 4 is made of a metal plate such as an aluminum plate having heat conductivity and being capable of dissipating heat. This metal plate is bent such that the mounting surface 43 is placed on the substrate 2, and the metal plate is screwed and fixed to the substrate 2 using a set screw 44. If the plurality of IC chips 3 (3A and 3B) are to be mounted on the substrate 2, chip pressing members 5 (5A and 5B) are provided on the top surface in areas corresponding to the areas where the IC chips are mounted.

As shown in FIG. 1B, if four IC chips 3 are mounted on the rectangular substrate 2, for example, the cover member 4 is also formed in a rectangular shape in a plan view. Further, in accordance with the number of the IC chips 3 mounted on the substrate 2, four chip pressing members 5 (5A, 5B, 5C, and 5D) are provided on the cover member 4 having a rectangular shape in a plan view. It is preferable that these chip pressing members 5 (5A to 5D) be also made of a metal plate having heat conductivity. These chip pressing members 5 can be made of portions of the top surface 41 of the cover member 4 having heat conductivity by a sheet metal processing technique. Alternatively, the chip pressing members may be made of other materials having heat conductivity, and may be bonded to the cover member 4, but there is no special limitation.

The respective chip pressing members 5 are formed to protrude to respective prescribed heights that allow the heat dissipation sheets 1 to be held by pressure between the respective IC chips 3 and the cover member 4. It is preferable that the heat dissipation sheets 1 be soft sheets made of silicon rubber or acrylic rubber having an excellent heat dissipation characteristic. This makes it easier to elastically press the heat dissipation sheets 1 by the chip pressing members 5, such that the heat dissipation sheets 1 are pressed on and come in contact with the IC chips 3.

With this configuration, heat in the IC chips 3 is immediately transmitted from the heat dissipation sheets 1 having heat conductivity to the cover member 4, which also functions as a heat dissipation plate, through the chip pressing members 5. Therefore, the heat from the IC chips 3 can be immediately dissipated.

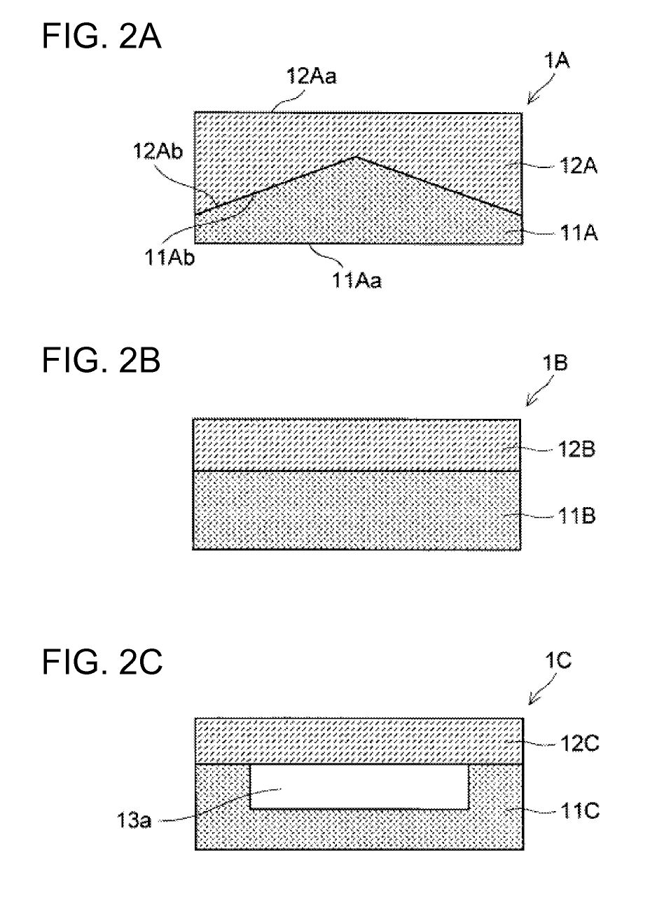

Next, a configuration of the heat dissipation sheet 1 in which the softer heat dissipation sheet and the harder heat dissipation sheet are laminated will be described with reference to FIGS. 2A to 2D.

It is preferable that the heat dissipation sheet 1 have a multilayer structure with a mountain-shaped pattern in a cross-sectional view as shown in a heat dissipation sheet 1A of Embodiment 1 in FIG. 2A, for example. The heat dissipation sheet 1A of Embodiment 1 is made of a first heat dissipation sheet 11A and a second heat dissipation sheet 12A. One heat dissipation sheet, which is the harder first heat dissipation sheet 11A, forms a mountain-shaped pattern in a cross-sectional view in which a center thereof is thick and a periphery thereof is thin in a thickness direction. This makes a bonding surface 11Ab have inclinations and form a protruding mountain shape. The other heat dissipation sheet, which is the softer second heat dissipation sheet 12A, forms a reverse mountain-shaped pattern in a cross-sectional view in which a center thereof is thin and a periphery thereof is thick in a thickness direction. This makes a bonding surface 12Ab have inclinations and form a recessed and reverse mountain (valley) shape.

With the above configuration, the harder heat dissipation sheet is made thick and the softer heat dissipation sheet is made thin in the center of the heat dissipation sheet 1. Therefore, the contact pressure in the center of the IC chip coming in contact with the heat dissipation sheet 1 is increased and not likely to be decreased whether it is configured such that a contact surface 11Aa of the first heat dissipation sheet 11A comes in contact with the IC chip or such that a contact surface 12Aa of the second heat dissipation sheet 12A comes in contact with the IC chip. As a result, the heat dissipation sheet can reliably come in contact with the entire surface of the IC chip with appropriate pressure. With this multilayer structure of having a mountain-shaped pattern in a cross-sectional view, the contact pressure of the heat dissipation sheet 1A on the IC chip is not decreased, and therefore, the heat dissipation characteristic is not degraded. This makes it possible to achieve a desired heat dissipation effect.

Further, the two rubber sheet-like heat dissipation sheets are laminated by bonding the bonding surfaces thereof, which have mountain-shaped patterns in a cross-sectional view. This way, the bonding strength is increased, and an effect of stabilizing this multilayer structure is achieved.

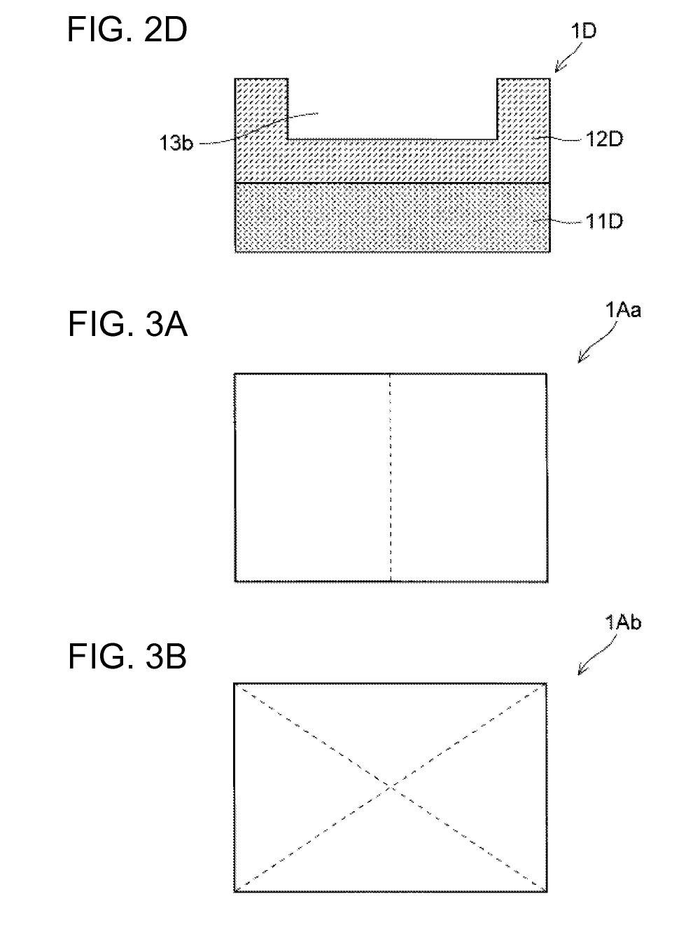

When the heat dissipation sheet has a rectangular shape in a plan view, the mountain shape can be formed to have a linear ridge as shown in the heat dissipation sheet 1Aa in a plan view of FIG. 3A. The heat dissipation sheet may have a quadrangular pyramid shaped mountain as in the heat dissipation sheet 1Ab shown in FIG. 3B, or may be formed in a circular shape in a plan view and has a circular cone-shaped mountain as in the heat dissipation sheet 1Ac shown in FIG. 3C. For convenience, a top of the conical mountain is indicated with a black dot in FIG. 3C.

Further, depending on the area and the thickness of the heat dissipation sheet, the heat dissipation sheet may have a plate-like multilayer structure of Embodiment 2 as shown in FIG. 2B. The multilayer structure may be a structure shown in a heat dissipation sheet 1B in which a harder first heat dissipation sheet 11B and a softer second heat dissipation sheet 12B are simply laminated.

With the above configuration, the heat dissipation sheet 1B can be easily pressed on the IC chip by the softer second heat dissipation sheet 12B. Further, the overlying harder heat dissipation sheet prevents the softer second heat dissipation sheet 12B from being deformed, and the contact pressure of the heat dissipation sheet 1B on the IC chip is prevented from being excessively decreased. Therefore, the heat dissipation sheet can come in contact with the IC chip with appropriate pressure.

The heat dissipation sheet 1A of Embodiment 1 and the heat dissipation sheet 1B of Embodiment 2 described above are mainly suited to IC chips that respectively have flat top surfaces. For a heat dissipation sheet for an IC chip having a protrusion in the center and having a mountain shape in a side view, a heat dissipation sheet having a multilayer structure shown in FIG. 2C or 2D, for example, can be used.

A heat dissipation sheet 1C of Embodiment 3 shown in FIG. 2C has a recess 13a in the center of a bonding surface of a harder first heat dissipation sheet 11C. The recess 13a has a size that substantially coincides with that of the IC chip on which the heat dissipation sheet is to be placed. A softer second heat dissipation sheet 12C has a plate-like shape. This results in a structure in which a hollow in a size that corresponds to that of the IC chip is formed in the center of a bonding portion where the first and second heat dissipation sheets are bonded to each other.

With the above multilayer structure of having the hollow in a size that substantially coincides with that of the IC chip on which the heat dissipation sheet 1C is to be placed, the softer heat dissipation sheet 12C is pressed on the IC chip with appropriate pressure. Also, because a region outside of the hollow in the softer heat dissipation sheet 12C is bonded to the harder heat dissipation sheet 11C, the softer heat dissipation sheet 12C is prevented from being deformed, and therefore, the heat dissipation sheet 1C can make uniform contact with the IC chip.

A heat dissipation sheet 1D of Embodiment 4 shown in FIG. 2D is made of a first heat dissipation sheet 11D and a second heat dissipation sheet 12D. Respective bonding surfaces of the first heat dissipation sheet 11D and the second heat dissipation sheet 12D are substantially flat. In the center of a contact surface of the softer second heat dissipation sheet, a recess 13b is made. The recess 13b has a size that substantially coincides with that of a protrusion of the IC chip on which the heat dissipation sheet is to be placed.

With this configuration, the softer second heat dissipation sheet 12D can be attached to cover the IC chip with the recess 13b that has a size that substantially coincides with that of the protrusion of the IC chip on which the heat dissipation sheet 1D is to be placed. Further, a region outside of the recess 13b in the softer heat dissipation sheet 12D is bonded to the harder first heat dissipation sheet 11D. As a result, the softer second heat dissipation sheet 12D is prevented from being excessively deformed, and therefore, the heat dissipation sheet 1D can make uniform contact with the IC chip with appropriate pressure.

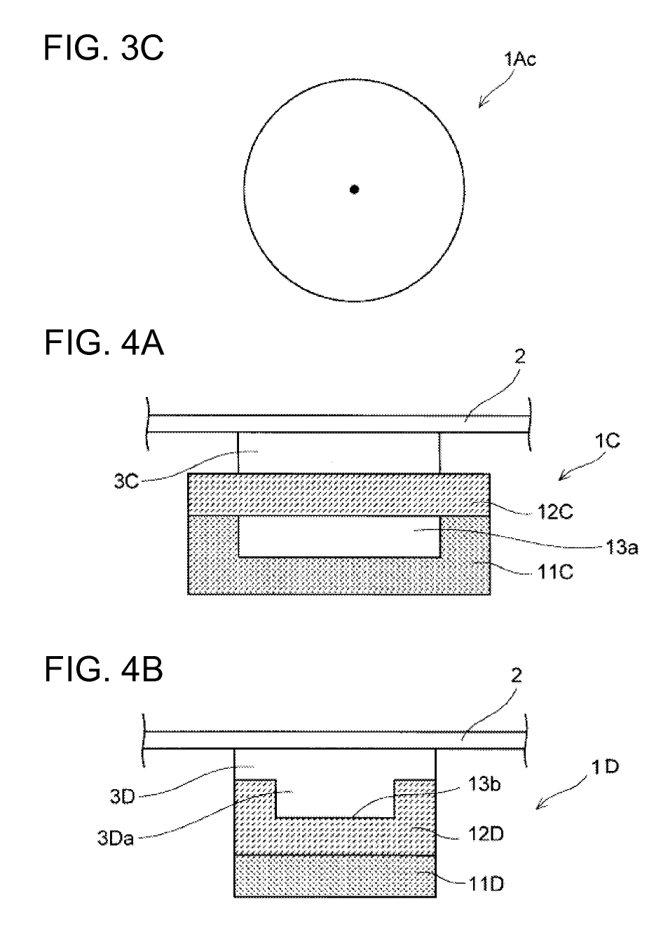

Next, examples of attaching the heat dissipation sheet 1C of Embodiment 3 and the heat dissipation sheet 1D of Embodiment 4 to the actual IC chips, respectively, will be described with reference to FIGS. 4A and 4B.

FIG. 4A shows an example of attaching the heat dissipation sheet of Embodiment 3 to the IC chip. FIG. 4B shows an example of attaching the heat dissipation sheet of Embodiment 4 to the IC chip.

FIG. 4A shows that the heat dissipation sheet 1C is placed on the IC chip 3C, which is mounted on the substrate 2, by having the softer second heat dissipation sheet 12C come in contact with the IC chip 3C. Further, the harder first heat dissipation sheet 11C has the recess 13a that has substantially the same size as that of the IC chip 3C. When this heat dissipation sheet 1C is pressed on the IC chip 3C (when the cover member is attached, for example), the softer second heat dissipation sheet 12C is elastically deformed and pressed on the IC chip 3C.

Even when the softer second heat dissipation sheet 12C is elastically deformed and pressed on the IC chip 3C, because the region outside of the recess 13a in the softer second heat dissipation sheet 12C is bonded to the harder first heat dissipation sheet 11C, the softer second heat dissipation sheet 12C is prevented from being deformed, and therefore, the heat dissipation sheet 1C can make uniform contact with the IC chip.

FIG. 4B shows that the heat dissipation sheet 1D is placed on a protrusion 3Da of the IC chip 3D, which is mounted on the substrate 2 and has a mountain shape in a side view, by having the recess 13b of the softer second heat dissipation sheet 12D cover the protrusion 3Da. When this heat dissipation sheet 1D is pressed on the IC chip 3D (when the cover member is attached, for example), the softer second heat dissipation sheet 12D is elastically deformed and is pressed on the IC chip 3D, while the harder first heat dissipation sheet 11D prevents the softer second heat dissipation sheet 12D from being deformed.

By making the respective bonding surfaces of the first and second heat dissipation sheets substantially flat, and by making a recess in a size that substantially coincides with that of the IC chip, on which the heat dissipation sheet is to be placed, in the center of the contact surface of the softer heat dissipation sheet, the softer heat dissipation sheet can be attached so as to cover the IC chip with the recess formed in a size that substantially coincides with that of the IC chip, on which the heat dissipation sheet is to be placed. Further, the region outside of the recess in the softer heat dissipation sheet is bonded to the harder heat dissipation sheet. Therefore, the softer heat dissipation sheet is prevented from being excessively deformed, and the heat dissipation sheet can make uniform contact with the IC chip with appropriate pressure.

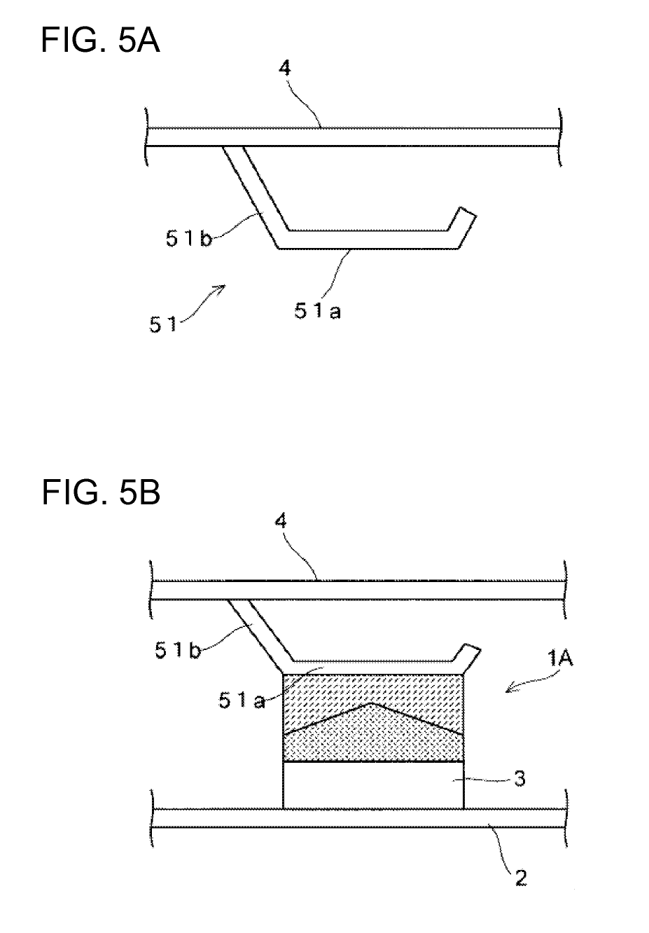

The heat dissipation sheet can come in contact with the IC chip even more reliably by using a chip pressing member formed on the cover member. A chip pressing member as a modified embodiment will be described with reference to FIGS. 5A and 5B.

The chip pressing member shown in FIG. 5A is an elastic pressing member 51 made of an elastic piece portion 51b and a contact piece portion 51a. One end of the elastic piece portion 51b is fixed to the cover member 4, and the elastic piece portion 51b is elastically moveable in a direction toward or away from the cover member. The contact piece portion 51a is connected to the other end of the elastic piece portion 51b, coming in contact with and pressing the heat dissipation sheet.

FIG. 5B shows a state in which the heat dissipation sheet 1A is actually disposed on the IC chip 3 that is mounted on the substrate 2, using the elastic pressing member 51.

As shown in FIG. 5B, the heat dissipation sheet 1A is pressed on the IC chip 3 by the contact piece portion 51a, and reliably comes in contact with a top surface of the IC chip 3. At this time, the elastic piece portion 51b is elastically deformed, and the contact piece portion 51a is given an elastic momentum toward the IC chip 3 and toward the top surface of the heat dissipation sheet 1A.

With this configuration, even if variation in a gap between the IC chip 3 and the cover member 4 is generated, the heat dissipation sheet 1 can come in contact with the IC chip 3 and with the cover member 4 with appropriate pressure. Therefore, it is possible to achieve a heat dissipation structure of an electronic device that allows heat to be dissipated sufficiently and that can improve reliability of the electronic device.

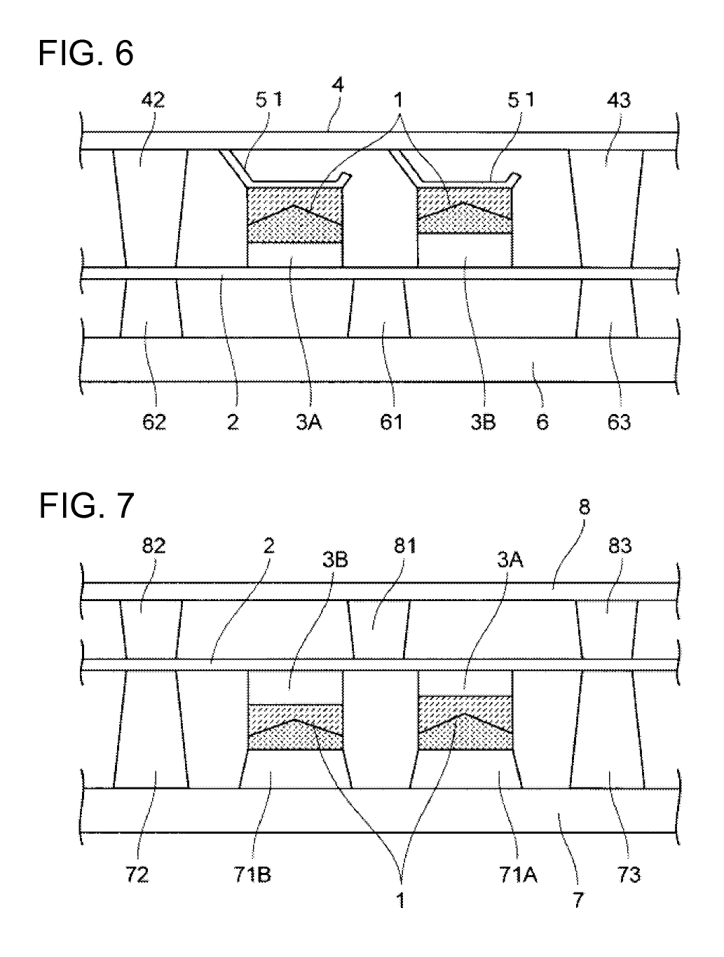

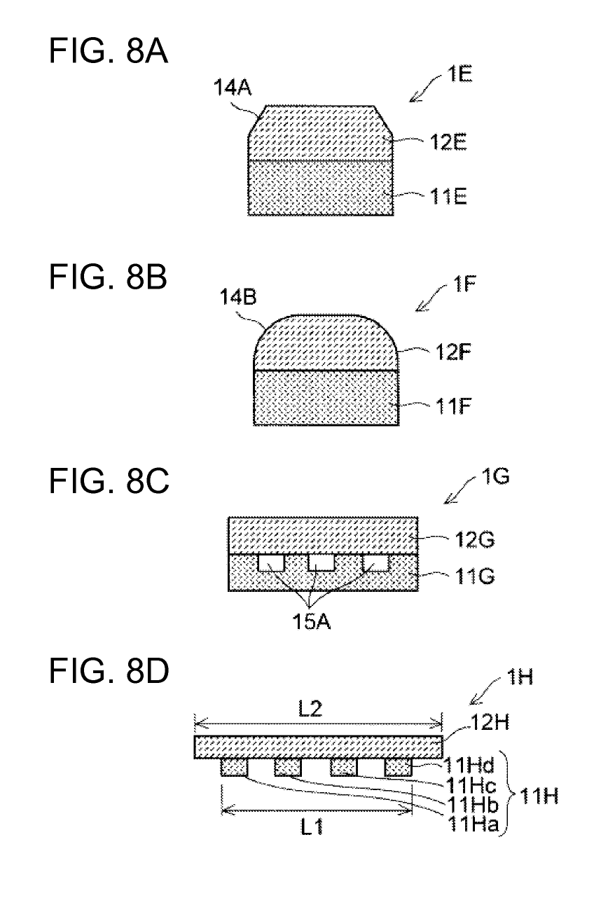

It is also possible to dissipate heat sufficiently by utilizing a structure in which the cover member 4 and a base member sandwich and support the substrate, thereby preventing the substrate from being deformed and allowing the heat dissipation sheet to make good contact with the IC chip. Such an embodiment will be described below, using a first modification example shown in FIG. 6 and a second modification example shown in FIG. 7.

In the first modification example shown in FIG. 6, the substrate 2 is sandwiched by substrate support legs 62 and 63 formed on a base member 6 and substrate support legs 42 and 43 formed on the cover member 4. The base member 6 has a middle portion support leg 61 that supports a middle portion between the IC chip 3A and the IC chip 3B. With this configuration, the substrate 2 can be prevented from being deformed. It is preferable to employ this configuration to prevent the substrate 2 from being bent or deformed when the heat dissipation sheet 1 and the IC chip are pressed to each other, making it possible to prevent the substrate from being damaged.

Even with the above configuration, because the heat dissipation sheets 1 mounted on the IC chips 3A and 3B are pressed on the IC chips 3A and 3B by the substrate pressing members (elastic pressing members 51) formed on the cover member 4, the heat dissipation sheets 1 can come in contact with the IC chips 3A and 3B and with the cover member 4 with appropriate pressure. Therefore, it is possible to achieve a heat dissipation structure of an electronic device that allows heat to be dissipated sufficiently and that can improve reliability of the electronic device.

In the second modification example shown in FIG. 7, the substrate 2 is placed with a mounting surface thereof facing down, and the substrate 2 is sandwiched and supported by substrate support legs 72 and 73 formed on a lower base member 7 and substrate support legs 82 and 83 formed on an upper base member 8. The upper base member 8 has a middle portion support leg 81 that supports a middle portion between the IC chip 3A and the IC chip 3B.

With this configuration, it is possible to prevent the substrate 2 from being bent or deformed. Therefore, even when the heat dissipation sheet 1 is pressed on the IC chip, the substrate is not damaged.

Further, by pressing the heat dissipation sheets 1 mounted on the IC chips 3A and 3B by substrate pressing members 71A and 71B formed on the lower base member 7, the heat dissipation sheets 1 can come in contact with the IC chips 3A and 3B and with the upper base member 8 with appropriate pressure. Therefore, it is possible to achieve a heat dissipation structure of an electronic device that allows heat to be dissipated sufficiently and that can improve reliability of the electronic device.

The substrate pressing members 71A and 71B may be pressing members that simply protrude to prescribed heights in the same manner as the chip pressing members 5 described above. The substrate pressing members 71A and 71B may also be elastically deformed with ease in the same manner as the elastic pressing piece member 51 described above.

In any case, as long as the substrate 2 is supported by being held from the two sides thereof, it becomes possible to prevent the substrate 2 from being bent or deformed, and therefore, the heat dissipation sheet can be pressed and mounted on the IC chip without damaging the substrate.

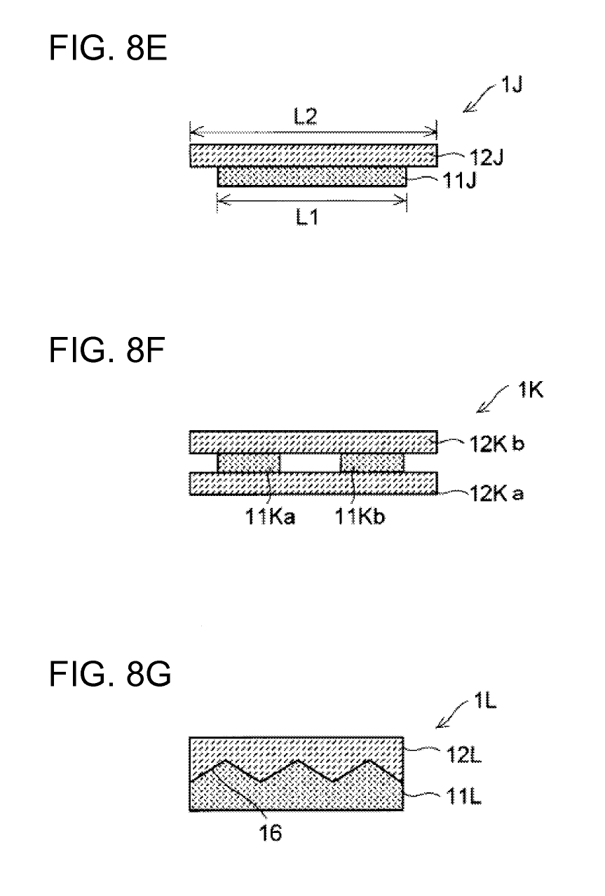

Further, various kinds of modifications can be applied in laminating the first heat dissipation sheet 11 and the second heat dissipation sheet 12 so as to make an attachment work easy. By these modifications, it is possible to obtain a heat dissipation structure that allows the heat dissipation sheets to be reliably bonded to each other and to come in contact with the IC chip and with the cover member with appropriate pressure and that can effectively dissipate heat. Here, respective embodiments will be described with reference to FIGS. 8A to 8G.

A heat dissipation sheet 1E shown in FIG. 8A has a structure in which a second heat dissipation sheet 12E having tapered-shaped corners 14A is overlaid on a first heat dissipation sheet 11E. If the heat dissipation sheet 1E has a rectangular shape, for example, edges on an entire circumference, which is four sides of the top surface, are tapered. With this configuration, the circumference of the top surface of the heat dissipation sheet bonded to the IC chip is cut in a tapered shape. This makes it difficult for the heat dissipation sheet to fall off upon being attached to the IC chip, and therefore, the heat dissipation sheet can be reliably attached to the IC chip.

A heat dissipation sheet 1F shown in FIG. 8B has a structure in which a second heat dissipation sheet 12F having circular arc-shaped corners 14B is overlaid on a first heat dissipation sheet 11F. If the heat dissipation sheet 1F has a rectangular shape, for example, edges on an entire circumference, which is four sides of the top surface, are rounded in a circular arc shape. With this configuration, the circumference of the top surface of the heat dissipation sheet bonded on the IC chip is rounded in a circular arc shape. This makes it difficult for the sheet to fall off upon being attached to the IC chip, and therefore, the heat dissipation sheet can be reliably attached to the IC chip.

A heat dissipation sheet 1G shown in FIG. 8C has a structure in which a plate-like second heat dissipation sheet 12G is overlaid on a first heat dissipation sheet 11G having a plurality of grooves on the contact surface thereof. With this configuration, when the heat dissipation sheet has a large surface area, variation in heights in a thickness direction is suppressed and contact pressure can be averaged by the plurality of grooves on the first heat dissipation sheet. Therefore, it becomes possible to prevent the contact pressure from being excessively decreased in the center of the IC chip that comes in contact with the heat dissipation sheet.

The grooves may have a triangular shape or may be grooves 15A having a rectangular shape as shown in FIG. 8C. It is more preferable to employ the grooves 15A in a rectangular shape that are easier to make. By making the grooves 15A having a rectangular shape, which are easy to make, contact pressure between the heat dissipation sheet and the IC chip, and between the heat dissipation sheet and the cover member can be averaged. Particularly, it becomes possible to prevent the contact strength from being excessively decreased in the center of the IC chip that comes in contact with the heat dissipation sheet. In case of making the grooves 15A having a rectangular shape, it is preferable that corners of the grooves be rounded, tapered, or the like to round off the edges such that the heat dissipation sheet would not be torn at the grooves.

A heat dissipation sheet 1H shown in FIG. 8D has a structure in which a second heat dissipation sheet 12H is overlaid on a first heat dissipation sheet 11H made of a plurality of strip-like narrow sheets 11Ha to 11Hd. Here, a width L2 of the second heat dissipation sheet 12H is wider than a width L1 of the first heat dissipation sheet 11H made of the plurality of narrow sheets 11Ha to 11Hd arranged to have a prescribed distance between each other.

With the above configuration, variation in heights in a thickness direction can be suppressed, and the contact pressure on the cover member can be averaged. Also, the contact strength can be prevented from being excessively decreased particularly in the center of the IC chip that comes in contact with the sheet. As shown in a heat dissipation sheet 1J shown in FIG. 8E, when laminating a second heat dissipation sheet 12J having the width L2 and a single first heat dissipation sheet 11J having the width L1, which is smaller than the width L2, the contact strength may be decreased in the center, because of bumps such as burrs, splits, or the like that are often formed at edges of the sheet as a result of cutting.

Therefore, for a heat dissipation sheet having a large surface area, it is preferable that the plurality of rectangular grooves 15A be provided as in the heat dissipation sheet 1G, or that the second heat dissipation sheet 12H be overlaid on the first heat dissipation sheet 11H, which is formed of the plurality of strip-like narrow sheets 11Ha to 11Hd, as in the heat dissipation sheet 1H.

As shown in a heat dissipation sheet 1K in FIG. 8F, it is also possible to suppress an adverse effect caused by bumps formed at the cut sections of the sheet by sandwiching two narrow first heat dissipation sheets 11Ka and 11Kb, which are placed to have a prescribed distance therebetween, with a pair of second heat dissipation sheets 12Ka and 12Kb that are wider than the two first heat dissipation sheets 11Ka and 11Kb. Even with such a sandwich structure as the heat dissipation sheet 1K, by appropriately combining the harder first heat dissipation sheet and the softer second heat dissipation sheet, it is possible to achieve a heat dissipation sheet structure that can address variation in the gap between the IC chip and the cover member with ease and that can come in contact with the IC chip and with the cover member with uniform contact pressure.

A heat dissipation sheet 1L shown in FIG. 8G has a structure of laminating a second heat dissipation sheet 12L and a first heat dissipation sheet 11L. The first heat dissipation sheet 11L has a wave-shaped contact surface having a plurality of mountain-shaped projections 16. The second heat dissipation sheet 12L has a wave-shaped contact surface that engages the wave-shaped surface of the first heat dissipation sheet 11L. This configuration can also prevent the adverse effect caused by bumps formed at the cutting section of the heat dissipation sheet, and even if heat dissipation sheets respectively having large surface areas are laminated on each other, variation in heights in a thickness direction can be suppressed and contact pressure on the cover member can be averaged. Therefore, it is preferable to employ this configuration.

As described above, by making a variety of changes to the size and shape of the laminated first and second heat dissipation sheets, it is possible to construct a heat dissipation structure that prevents the heat dissipation sheets from falling during an attachment work, thereby making the attachment work easier and that allows the heat dissipation sheet to reliably come in contact with the entire surface of the IC chip with appropriate contact pressure, ensuring the effective heat dissipation.

Further, in order to easily distinguish the first heat dissipation sheet from the second heat dissipation sheet that is to be overlaid on the first heat dissipation sheet, it is preferable that the respective sheets have mutually different hues. With this configuration, the first heat dissipation sheet and the second heat dissipation sheet can be reliably laminated without confusing the two during the attachment work.

As described above, according to the present invention, the heat dissipation sheet has a double-layered structure in which the softer heat dissipation sheet and the harder heat dissipation sheet are laminated. Therefore, it becomes easy to address variation in the gap between the IC chip and the cover member by the softer heat dissipation sheet interposed therebetween. Further, because of the harder heat dissipation sheet, the heat dissipation sheet and the IC chip can come in contact with each other with uniform contact pressure.

According to the present invention, even if variation in the gap between the IC chip and the cover member is generated, the heat dissipation sheet can come in contact with the IC chip and with the cover member with appropriate pressure. As a result, it is possible to achieve a heat dissipation structure of an electronic device that dissipates heat sufficiently and that can improve reliability of the electronic device.

Further, the harder heat dissipation sheet has a mountain shape in a cross-sectional view by making the center thereof thick and by making the periphery thereof thin. This way, the contact pressure on the IC chip in the center is increased, and therefore, the heat dissipation sheet can come in contact with a surface of the IC chip more reliably.

Further, it becomes possible to prevent the substrate from being bent or deformed by disposing the substrate pressing member or the substrate support leg formed on the cover member. Therefore, the heat dissipation sheet can come in contact with the IC chip with appropriate pressure without damaging the substrate, and a desired heat dissipation effect can be achieved.

### INDUSTRIAL APPLICABILITY

A heat dissipation structure of an electronic device according to the present invention can be suitably used for an electronic device that is required to reliably dissipate heat generated in IC chips.

### DESCRIPTION OF REFERENCE CHARACTERS

1 heat dissipation sheet

1A heat dissipation sheet (Embodiment 1)

1B heat dissipation sheet (Embodiment 2)

1C heat dissipation sheet (Embodiment 3)

1D heat dissipation sheet (Embodiment 4)

1E to 1L heat dissipation sheet (another embodiment)

2 substrate

3 IC chip

4 cover member

5 substrate pressing member

51 elastic pressing member

6 base member

11 (11A to 11L) first heat dissipation sheet

12 (12A to 12L) second heat dissipation sheet

14A tapered corner

14B circular arc-shaped corner

15A rectangular groove

16 mountain-shaped projection

42, 43 substrate support leg

62, 63 substrate support leg

1. A heat dissipation structure of an electronic device, comprising: a substrate having an IC chip, which is an electronic component that becomes a heat generating element, mounted thereon; a cover member that covers a mounting surface of the substrate and that has a heat dissipation characteristic; and a heat dissipation sheet interposed and pressed between the IC chip and the cover member, the heat dissipation structure dissipating heat through the heat dissipation sheet and the cover member,
wherein the heat dissipation sheet has a double-layered structure in which a first dissipation sheet and a second heat dissipation sheet are laminated in a thickness direction, and
wherein a rubber hardness of the first heat dissipation sheet differs from that of the second heat dissipation sheet so that a softer heat dissipation sheet and a harder heat dissipation sheet are laminated in a direction of a gap between the IC chip and the cover member.

2. The heat dissipation structure of the electronic device according to claim 1,
wherein the first heat dissipation sheet has a chip contact surface with which the IC chip comes in contact and a bonding surface on which the second heat dissipation sheet is bonded, the second heat dissipation sheet has a bonding surface on which the first heat dissipation sheet is bonded and a cover contact surface with which the cover member comes in contact, and the respective contact surfaces are substantially flat, and
wherein one heat dissipation sheet, which is harder, is made thick in a center and is made thin in a periphery in a thickness direction such that the bonding surface thereof forms a mountain shape in a cross-sectional view, and the other heat dissipation sheet, which is softer, is made thin in a center and is made thick in a periphery in a thickness direction such that the bonding surface thereof forms a reverse mountain shape in a cross-sectional view.

3. The heat dissipation structure of the electronic device according to claim 1,
wherein the first heat dissipation sheet has a chip contact surface with which the IC chip comes in contact and a bonding surface on which the second heat dissipation sheet is bonded, the second heat dissipation sheet has a bonding surface on which the first heat dissipation sheet is bonded and a cover contact surface with which the cover member comes in contact, and the respective contact surfaces are substantially flat, and
wherein a recess in a size that substantially coincides with that of the IC chip having the heat dissipation sheet placed thereon is made in a center of the contact surface of one heat dissipation sheet, which is harder, and a hollow in a size corresponding to that of the IC chip is made in a center of a contact portion where the first heat dissipation sheet comes in contact with the second heat dissipation sheet.

4. The heat dissipation structure of the electronic device according to claim 1,
wherein the first heat dissipation sheet has a chip contact surface with which the IC chip comes in contact and a bonding surface on which the second heat dissipation sheet is bonded, the second heat dissipation sheet has a bonding surface on which the first heat dissipation sheet is bonded and a cover contact surface with which the cover member comes in contact, and the respective contact surfaces are substantially flat, and
wherein a recess in a size that substantially coincides with that of the IC chip having the heat dissipation sheet placed thereon is made in a center of the contact surface of the softer heat dissipation sheet.

5. The heat dissipation structure of the electronic device according to claim 1, wherein a chip pressing member is provided on the cover member, and the chip pressing member presses each of the first and second heat dissipation sheets on the IC chip.

6. The heat dissipation structure of the electronic device according to claim 5, wherein the chip pressing member is an elastic pressing member provided with an elastic piece portion that is fixed to the cover member on one end and that is elastically moveable in a direction toward or away from the cover member, and a contact piece portion that is connected to the other end of the elastic piece portion and that makes contact with the IC chip.

7. The heat dissipation structure of the electronic device according to claim 5, wherein a base member having a substrate support leg that supports the substrate is provided on a rear surface of the substrate, a substrate support member that supports the substrate by sandwiching the substrate with the substrate support leg is provided on the cover member, and a middle portion support leg that supports a middle portion between a plurality of said chip pressing members is provided on the base member.

8. The heat dissipation structure of the electronic device according to claim 1, wherein the first heat dissipation sheet has a different hue from that of the second heat dissipation sheet.

9. The heat dissipation structure of the electronic device according to claim 2, wherein a top surface of the second heat dissipation sheet, which corresponds to the cover contact surface, has a periphery thereof cut in a tapered shape.

10. The heat dissipation structure of the electronic device according to claim 2, wherein a top surface of the second heat dissipation sheet, which corresponds to the cover contact surface, has a periphery thereof rounded in a circular arc shape.

11. The heat dissipation structure of the electronic device according to claim 2, wherein the first heat dissipation sheet has a plurality of grooves on the bonding surface, and the plate-like second heat dissipation sheet is overlaid thereon.

12. The heat dissipation structure of the electronic device according to claim 11, wherein the grooves are rectangular.

13. The heat dissipation structure of the electronic device according to claim 2, wherein the first heat dissipation sheet is formed of a plurality of strip-like narrow sheets that are arranged to have a prescribed distance between each other, and the second heat dissipation sheet, which has a width wider than that of the first heat dissipation sheet, is overlaid on the first heat dissipation sheet.

14. The heat dissipation structure of the electronic device according to claim 2, wherein, in the first heat dissipation sheet, the chip contact surface has a plurality of mountain-shaped protrusions that make the chip contact surface have a wave shape, and the second heat dissipation sheet, which has a wave-shaped contact surface that engages the wave shape of the first heat dissipation sheet, is overlaid on the first heat dissipation sheet.
